(19) United States
(12) Patent Application Publication
(10) Pub. No.: US 2022/0026499 A1
(43) Pub. Date: Jan. 27, 2022

(54) Method and System for Monitoring Health Condition of Battery Pack

(71) Applicant: Guangzhou Automobile Group Co., Ltd., Guangzhou (CN)

(72) Inventors: Yizhen ZHANG, Guangzhou (CN); Yonggang XU, Guangzhou (CN); Tonatiuh RANGEL, Guangzhou (CN); Hongzhong QI, Guangzhou (CN); Jin SHANG, Guangzhou (CN)

(21) Appl. No.: 16/937,575

(22) Filed: Jul. 23, 2020

(51) Int. Cl. G01R 31/392; G01R 31/36; G01R 31/3835; G01R 31/396

(52) U.S. Cl. CPC G01R 31/392; G01R 31/396; G01R 31/3835; G01R 31/3646

(57) ABSTRACT

Provided are a method and a system for monitoring the health condition of a battery pack. The method includes: obtaining data of voltage difference between the maximum and minimum voltages of the battery cells within a battery pack of an electric vehicle; determining an alert value based on the data of voltage difference, wherein the alert value is a combined value of the following factors: the slope of the mean battery cell voltage difference within a preset period of past time, the predicted mean battery cell voltage difference within a preset period of future time, and the minimum of battery cell voltage difference; generating a predictive maintenance notice for the battery pack of the electric vehicle when the alert value is larger than a threshold value.

### TECHNICAL FIELD

The present disclosure relates to the field of electric vehicles, and particularly to a method and system for monitoring the health condition of a battery pack.

### BACKGROUND

At present, as people pay more attention to the environment problems, new energy vehicles (NEVs) are increasingly accepted by more people. NEVs include, among others, electric vehicles (EVs), hybrid electric vehicles (HEVs), and plug-in hybrid electric vehicles (PHEVs). NEVs may transmit real-time vehicular data to Internet cloud servers for remote monitoring and data collecting. As a result, significant amount of data for NEV models has accumulated over time. Hidden in the data are valuable clues regarding the performance and health of the NEV, especially the battery pack, which is a key component of NEVs.

An effective way to monitor the battery pack health conditions for NEVs needs to be established based on the valuable data.

It is to be noted that the information disclosed in this background of the disclosure is only for enhancement of understanding of the general background of the present disclosure and should not be taken as an acknowledgement or any form or suggestion that this information forms the prior art already known to a person skilled in the art.

### SUMMARY

Embodiments of the present disclosure provide methods and system for monitoring the health condition of a battery pack, and intend to solve the problem of how to establish an effective way to monitor the battery pack health conditions of NEVs.

According to an embodiment of the present disclosure, a method for monitoring the health condition of a battery pack is provided, and the method includes: obtaining data of voltage difference between the maximum and minimum voltages of the battery cells within a battery pack of an electric vehicle; determining an alert value based on the data of voltage difference, wherein the alert value is a combined value of the following factors: the slope of the mean battery cell voltage difference within a preset period of past time, the predicted mean battery cell voltage difference within a preset period of future time, and the minimum of battery cell voltage difference; generating a predictive maintenance notice for the battery pack of the electric vehicle when the alert value is larger than a threshold value.

In an exemplary embodiment, before the step of obtaining the data of voltage difference between the maximum and minimum voltages of the battery cells within a battery pack of an electric vehicle, the method may further includes: reporting, by on-board sensors and/or CAN bus, relevant data of individual battery cell voltages of the battery pack of the electric vehicle.

In an exemplary embodiment, the step of determining an alert value based on the historical data of voltage difference may include: analyzing, by a cloud-based server or an on-board computing device, a time series of relevant data of individual battery cell voltages of the battery pack to obtain the alert value.

In an exemplary embodiment, wherein the alert value is a weighted average of the slope of the mean battery cell voltage difference, the prediction of future mean battery cell voltage difference, and the minimum of battery cell voltage difference.

In an exemplary embodiment, wherein the alert value L_{d} for a given time period is determined by the following formulas:

L_{d}=W₁*L₁+W₂*L₂+W₃*L₃, W₁+W₂+W₃=1;

wherein L₁, L₂ and L₃ respectively represent the slope of the mean battery cell voltage difference, the prediction of future mean battery cell voltage difference, and the minimum of battery cell voltage difference; W₁, W₂ and W₃ are non-negative weight coefficients for L₁, L₂ and L₃, respectively.

In an exemplary embodiment, W₁, W₂, and W₃ are determined according to the type of the battery pack.

In an exemplary embodiment, the method further includes: obtaining a present alert value based on the alert values L_{d}, wherein the present alert value is a weighted average of the alert values over a preset number of time periods.

In an exemplary embodiment, wherein the current alert Lₚ is determined by the following formula:

$${L}_{p} = \frac{{\sum }_{n = 1}^{N} ( {w}_{n} {L}_{d , n} )}{{\sum }_{n = 1}^{N} {w}_{n}}$$

wherein N represents the lookback window in time periods, wₙ represents a weight coefficient of the n^{th} time period.

In an exemplary embodiment, the method further includes: optimizing the threshold value based on current reports of electric vehicles with battery pack error reported and electric vehicles with no battery pack error reported.

In an exemplary embodiment, after the step of generating a predictive maintenance notice for the battery pack of the electric vehicle when the alert value is larger than a threshold value, the method further includes: sending the predictive maintenance notice to a designated terminal.

According to another embodiment of the present disclosure, a system for monitoring the health condition of a battery pack is provided. The system may include: an obtaining module, configured to obtain data of voltage difference between the maximum and minimum voltages of the battery cells within a battery pack of an electric vehicle; a computing module, configured to calculate an alert value based on the data of voltage difference, wherein the alert value is a combined value of the following factors: the slope of the mean battery cell voltage difference within a preset period of past time, the predicted mean battery cell voltage difference within a preset period of future time, and the minimum of battery cell voltage difference; a generating module, configured to generate a predictive maintenance notice for the battery pack of the electric vehicle when the alert value is larger than a threshold value.

In an exemplary embodiment, wherein the alert value is a weighted average of the slope of the mean battery cell voltage difference, the predicted future mean battery cell voltage difference, and the minimum of battery cell voltage difference.

In an exemplary embodiment, wherein the alert value L_{d} for a given time period is determined by the following formulas:

L_{d}=W₁*L₁+W₂*L₂+W₃*L₃, W₁+W₂+W₃=1;

wherein L₁, L₂ and L₃ respectively represent the slope of the mean battery cell voltage difference, the predicted future mean battery cell voltage difference, and the minimum of battery cell voltage difference; W₁, W₂ and W₃ are non-negative weight coefficients for L₁, L₂ and L₃, respectively.

In an exemplary embodiment, W₁, W₂ and W₃ are determined according to the type of the battery pack.

In an exemplary embodiment, the computing module is further configured to obtain a present alert value based on the alert values L_{d}, wherein the present alert value is a weighted average of the alert values over a preset number of time periods.

In an exemplary embodiment, wherein the current alert Lₚ is determined by the following formula:

$${L}_{p} = \frac{{\sum }_{n = 1}^{N} ( {w}_{n} {L}_{d , n} )}{{\sum }_{n = 1}^{N} {w}_{n}}$$

wherein, N represents the lookback window in time periods, wₙ represents a weight coefficient of the n^{th} time period.

In an exemplary embodiment, the system further includes: an optimizing module, configured to optimize the threshold value based on current reports of electric vehicles with battery pack error reported and electric vehicles with no battery pack error reported.

In an exemplary embodiment, the system further includes: a sending module, configured to send the predictive maintenance notice to a designated terminal.

In an embodiment of the present disclosure, a non-volatile computer readable storage medium is provided, a program is stored in the non-volatile computer readable storage medium, and the program is configured to be executed by a computer to perform the steps of methods in above-mentioned embodiments.

In an embodiment of the present disclosure, an electric vehicle is provided. The electric vehicle includes the system for monitoring the health condition of a battery pack in above-mentioned embodiments.

Through the above-mentioned embodiments of the present disclosure, an alert value is obtained by analyzing the relevant data of voltage difference of the battery pack. Based on the alert values, any abnormal battery pack degradation trend can be detected, and early warnings can be provided to OEMs, dealerships, and end customers. Furthermore, troubleshooting and predictive maintenance work can be performed at dealerships as soon as required to extend battery life span and reduce warranty costs.

### BRIEF DESCRIPTION OF THE DRAWINGS

The drawings described here are adopted to provide a further understanding to the present disclosure and form a part of the application. Schematic embodiments of the present disclosure and descriptions thereof are adopted to explain the present disclosure and not intended to form limits to the present disclosure. In the drawings:

FIG. 1 is a flowchart of a method for monitoring the health condition of a battery pack according to an embodiment of the present disclosure;

FIG. 2 is a flowchart of a method for monitoring the health condition of a battery pack according to another embodiment of the present disclosure;

FIG. 3 is a schematic diagram of alert distribution comparison between error reported and no error reported groups according to an embodiment of the present disclosure;

FIG. 4 is an ROC curve of the alert model according to an embodiment of the present disclosure;

FIG. 5 is a structure block diagram of a system for monitoring the health condition of a battery pack according to an embodiment of the present disclosure;

FIG. 6 is a structure block diagram of a system for monitoring the health condition of a battery pack according to another embodiment of the present disclosure; and

FIG. 7 is a structure block diagram of an electric vehicle according to an embodiment of the present disclosure.

### DETAILED DESCRIPTION OF THE EMBODIMENTS

The present disclosure will be described below with reference to the drawings and in combination with the embodiments in detail. It is to be noted that the embodiments in the application and characteristics in the embodiments may be combined without conflicts.

### Embodiment 1

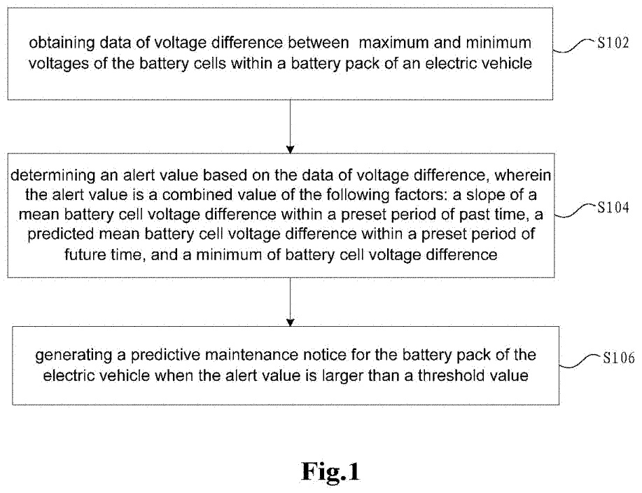

In order to establish an effective way to monitor the battery pack health, in the present embodiment, a data-driven battery pack health monitoring method is provided based on the relevant data of individual battery cell voltages of the battery pack. As shown in FIG. 1, the method includes the following steps.

At S102, obtain data of voltage difference between the maximum and minimum voltages of the battery cells within a battery pack of an electric vehicle.

At S104, determine an alert value based on the data of voltage difference, wherein the alert value is a combined value of the following factors: the slope of the mean battery cell voltage difference within a preset period of past time, the predicted mean battery cell voltage difference within a preset period of future time, and the minimum of battery cell voltage difference.

At S106, generate a predictive maintenance notice for the battery pack of the electric vehicle when the alert value is larger than a threshold value.

Through the above steps, an alert value is obtained by analyzing the relevant data of voltage difference of the battery pack. Based on the alert values, any abnormal battery pack degradation trend can be detected, and early warnings can be provided to OEMs, dealerships, and end customers. Furthermore, troubleshooting and predictive maintenance work can be performed at dealerships as soon as required to extend battery life span and reduce warranty costs.

In an exemplary embodiment, before the step of S102, the method may further include the following step: on-board sensors and/or CAN bus report relevant data of individual battery cell voltages of the battery pack of the electric vehicle.

For example, it is possible to measure the voltages of the battery cells using voltage sensors which are connected to each of the cells. As such, the measurement can be made when the vehicle is in use. The voltage sensors can further improve reliability in the measured data, by measuring voltage of the cells for one or more seconds in real time at a predetermined sampling period.

In an exemplary embodiment, the step of S104 may further include the following step: analyzing a time series of relevant data of individual battery cell voltages of the battery pack to obtain the alert values through a cloud-based server or an on-board computing device.

In an exemplary embodiment, wherein the alert value is a weighted average of the slope of the mean battery cell voltage difference, the predicted future mean battery cell voltage difference, and the minimum of battery cell voltage difference.

In an exemplary embodiment, the method further includes the following step: obtaining a present alert value based on the alert values, wherein the present alert value is a weighted average of the alert values over a preset number of time periods.

In an exemplary embodiment, the method further includes the following step: optimizing the threshold value based on current reports of electric vehicles with battery pack error reported and electric vehicles with no battery pack error reported.

In an exemplary embodiment, after the step S106, the method further includes the following step: sending the predictive maintenance notice to a designated terminal.

### Embodiment 2

In the present embodiment, an alert model is provided. The proposed alert model can be applied to analyze relevant data stored in the cloud server and generate automatic predictive maintenance notices for battery packs of different kinds of NEVs (e.g. EV, HEV, PHEV, etc.). The battery life span can be extended to create better customer experience, and warranty costs can be greatly reduced if troubleshooting and predictive maintenance actions are performed shortly after early warning notices are issued. The highest level of predictive maintenance and customer satisfaction can be achieved with the proposed method, instead of reactive maintenance which results in poor customer experiences and higher warranty expenses for OEMs.

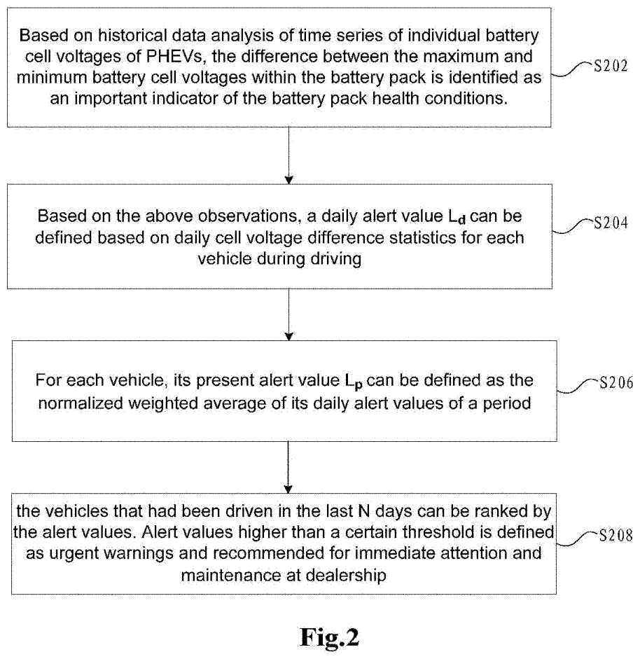

FIG. 2 is a flowchart according to an example of the present disclosure. It is to be noted that the method shown in FIG. 2 is applicable to all types of NEVs, and the PHEV here is exemplary. As shown in FIG. 2, the process mainly includes the following steps.

At S202, based on historical data analysis of time series of individual battery cell voltages of one type of PHEVs that had several reported battery pack failures, the difference between the maximum and minimum battery cell voltages within the battery pack is identified as an important indicator of the battery pack health conditions.

For the battery pack to operate normally, it is necessary to keep the battery cell voltage difference in a very small range most of the time. Abnormal battery pack degradation was observed on some vehicles when the cell voltage difference increased steadily, and battery capacity could have dropped unusually at the same time. It turned out that the abnormal battery pack degradation trend could be corrected with BMS software update and consistent regular charging behaviors afterwards.

At S204, based on the above observations, a daily alert value L_{d} can be defined based on daily cell voltage difference statistics for each vehicle during driving, which is a combined value of the following three elements.

The first element is the slope of the daily mean cell voltage difference of a period. For example, the slope can be the time-series trend of the daily mean cell voltage difference over the last 30 days.

The second element is the prediction of future daily mean cell voltage difference based on the current cell voltage difference and time-series trend. For example, a daily mean cell voltage difference in the next 30 days could be predicted based on the current cell voltage difference and time-series trend of cell voltage difference in the past 30 days.

The third element is the daily minimum of battery cell voltage difference. Multiple daily battery cell voltage difference can be measured and collected, from which the minimum of daily battery cell voltage difference can be selected.

It into be noted that in the present embodiment, “daily” is just an example, and it may be another time period, without limitation, such as hourly or every N hours or N days, etc.

In the present embodiment, different threshold values can be defined for the above three elements for different vehicle battery types as required, and the ratios between the actual values and the threshold values can be defined as different alert elements, i.e., L₁, L₂, and L₃. For example, the daily alert value L_{d} can be defined as the weighted average of the above three alert elements according to the following formulas:

L_{d}=w₁*L₁+w₂*L₂+w₃*L₃ (1)

w₁+w₂+w₂=1 (2)

At S206, for each vehicle, its present alert value Lₚ can be defined as the normalized weighted average of its daily alert values of a period (e.g. last N days). For example, the weight of last day is 1, and the weights decay exponentially for days earlier than the last day. For example, the present alert value. Lₚ can be defined according to the formula as below:

$${L}_{p} = \frac{{\sum }_{n = 1}^{N} ( {w}_{n} {L}_{d , n} )}{{\sum }_{n = 1}^{N} {w}_{n}} \qquad ( 3 )$$

At S208, all the vehicles that had been driven in the last N days can be ranked by the present alert values. Alert values higher than a certain threshold can be defined as urgent warnings and recommended for immediate attention and maintenance at dealerships.

In the present embodiment, the proposed alert model results are verified with battery pack error report. The alert values on the day when customers reported battery pack error to the dealership can be calculated and compared with the present alert values of all active vehicles.

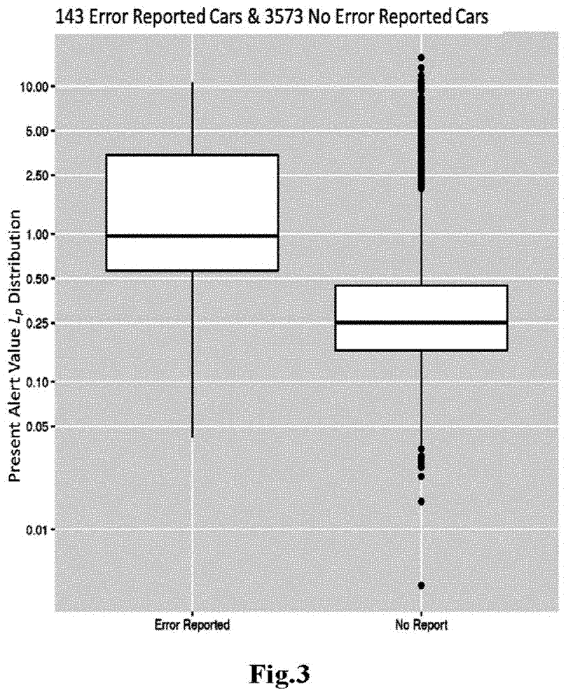

FIG. 3 is a schematic diagram of alert value distribution comparison between error reported and no error reported groups. As shown in FIG. 3, for one type of PHEV studied, the alert value distributions are significantly different for vehicles with error reported and vehicles with no error reported. For error reported vehicles, the median alert value is about 1. For no error reported vehicles, the median alert value is about 0.25.

Based on the results shown in FIG. 3, 0.5 can be defined as the threshold value between normal and abnormal alert groups, and the corresponding true positive rate of the alert model is 83%, false negative rate is 17%, and false positive rate is 22%.

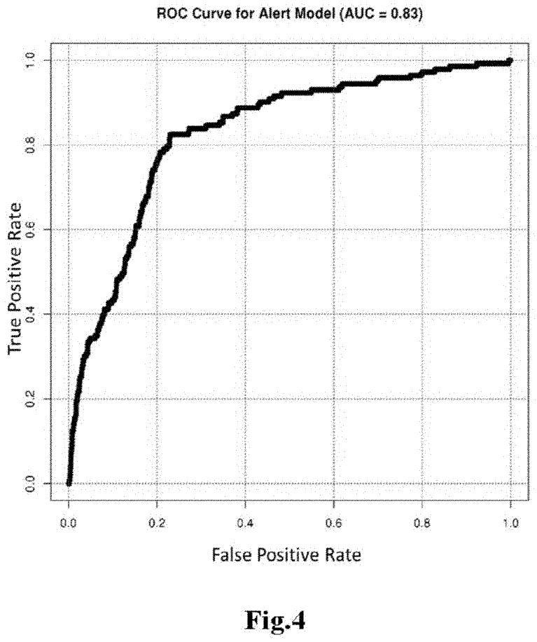

When different values are defined as the threshold between normal and abnormal groups, different model true positive rate and false positive rate can be obtained, resulting in the ROC curve as shown in FIG. 4. The area under the ROC curve (AUC)>0.8 indicates the alert model's effectiveness.

In the present embodiment, the weights in formula (1) and formula (2) are trained and optimized. So is the decaying scheme for the weights in formula (3). In one implementation, based on training data of vehicles with and without reported errors, the parameters are chosen so that AUC values are maximized.

Through the descriptions about the above implementation modes, those skilled in the art may clearly know that the methods according to the embodiments may be implemented in a manner of combining software and a required universal hardware platform and, of course, may also be implemented through hardware. However, the former is a preferred implementation mode under many circumstances. Based on such an understanding, the technical solutions of the present disclosure substantially contributing to the conventional art may be embodied in form of software product. The computer software product is stored in a storage medium (for example, a Read-Only Memory (ROM)/Random Access Memory (RAM), a magnetic disk and an optical disk), including a plurality of instructions configured to enable a terminal device (which may be a mobile phone, a computer, a server, a network device or the like) to execute the methods of each embodiment of the present disclosure.

### Embodiment 3

In the embodiment, a system for monitoring the health condition of a battery pack is also provided. The system can be applied to a cloud-based server or an on-board computing device, and is configured to implement the abovementioned embodiments with preferred implementation modes. What has been described will not be elaborated. For example, term “module”, used below, may be a combination of software and/or hardware realizing a predetermined function. Although the device described in the following embodiment is preferably implemented by the software, implementation by the hardware or the combination of the software and the hardware is also possible and conceivable.

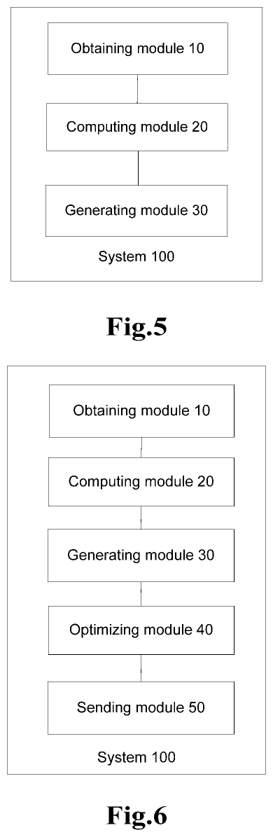

FIG. 5 is a structure block diagram of a system for monitoring the health condition of a battery pack according to an embodiment of the present disclosure. As shown in FIG. 5, the system 100 includes:

an obtaining module 10, which is configured to obtain data of voltage difference between the maximum and minimum voltages of the battery cells within a battery pack of an electric vehicle.

a computing module 20, which is configured to calculate an alert value based on the data of voltage difference, wherein the alert value is a combined value of the following factors: the slope of the mean battery cell voltage difference within a preset period of past time, the predicted mean battery cell voltage difference within a preset period of future time, and the minimum of battery cell voltage difference.

a generating module 30, which is configured to generate a predictive maintenance notice for the battery pack of the electric vehicle when the alert value is larger than a threshold value.

FIG. 6 is another structure block diagram of a system for monitoring the health condition of a battery pack according to an embodiment of the present disclosure. As shown in FIG. 6, the system further includes:

an optimizing module 40, which is configured to optimize the threshold value based on current reports of electric vehicles with battery pack error reported and electric vehicles with no battery pack error reported.

a sending module 50, which is configured to send the predictive maintenance notice to a designated terminal.

In the present embodiment, the system can be implemented in a cloud-based server or an on-board computing device. It can analyze the time series of relevant data provided by on-board sensors and/or CAN bus, identify all the vehicles with any unhealthy degradation trend, and generate automatic predictive maintenance warning notices for battery packs of different kinds of NEVs (e.g. EV, HEV, PHEV, etc.). It will make sure all the actively running battery packs operate within a healthy cell voltage difference range and detect any battery pack potential imbalance issues or unhealthy degradation trend in the early stage. Once a reasonable alert threshold has been determined for a vehicle model, the “maintenance needed” warnings can be sent to OEMs, dealerships, and customers directly in different formats, so that troubleshooting and predictive maintenance actions can be taken early to extend battery life span and avoid costly warranty loss for OEMs.

### Embodiment 4

According to the present embodiment, a non-volatile computer readable storage medium is provided, a program is stored in the non-volatile computer readable storage medium, and the program is configured to be executed by a computer to perform the following steps.

At S1, obtain data of voltage difference between the maximum and minimum voltages of the battery cells within a battery pack of an electric vehicle.

At S2, determine an alert value based on the data of voltage difference, wherein the alert value is a combined value of the following factors: the slope of the mean battery cell voltage difference within a preset period of past time, the predicted mean battery cell voltage difference within a preset period of future time, and the minimum of battery cell voltage difference.

At S3, generate a predictive maintenance notice for the battery pack of the electric vehicle when the alert value is larger than a threshold value.

In an example embodiment, the storage medium may include, but not limited to, various media capable of storing program codes such as a U disk, a ROM, a RAM, a mobile hard disk, a magnetic disk or an optical disk.

### Embodiment 5

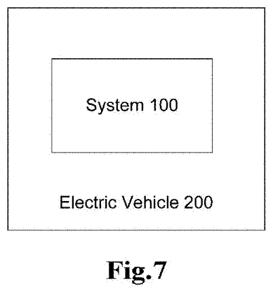

According to the present embodiment, an electric vehicle is provided. As shown in FIG. 7, the electric vehicle includes the system for monitoring the health condition of a battery pack in above-mentioned embodiments. It is to be noted that in the present embodiment the electric vehicle can be different kinds of NEVs, e.g. EV, HEV, PHEV, etc.

In the present embodiment, the system can analyze the relevant data of the battery packs provided by on-board sensors and/or CAN bus, and identify all the vehicles with any unhealthy degradation trends, and generate automatic predictive maintenance warning notices for battery packs of the NEVs. It will make sure all the actively running battery packs operate within a healthy cell voltage difference range and detect any battery pack potential imbalance issues or unhealthy degradation trend in the early stage. Once a reasonable alert threshold has been determined for a vehicle model, the warnings can be sent to OEMs, dealerships, or customers directly in different formats, so that troubleshooting and predictive maintenance actions can be taken early to extend battery life span and avoid costly warranty loss for OEMs.

It is apparent that those skilled in the art should know that each module or each step of the present disclosure may be implemented by a universal computing device, and the modules or steps may be concentrated on a single computing device or distributed on a network formed by a plurality of computing devices, and may in an embodiment be implemented by program codes executable for the computing devices, so that the modules or the steps may be stored in a storage device for execution with the computing devices, the shown or described steps may be executed in sequences different from those described here in some circumstances, or may form individual integrated circuit module respectively, or multiple modules or steps therein may form a single integrated circuit module for implementation. Therefore, the present disclosure is not limited to any specific hardware and software combination.

The above is only the exemplary embodiments of the present disclosure and not intended to limit the present disclosure. For those skilled in the art, the present disclosure may have various modifications and variations. Any modifications, equivalent replacements, improvements and the like made within the spirit and principle of the present disclosure shall fall within the scope of protection of the present disclosure.

What is claimed is:

1. A method for monitoring a health condition of a battery pack, comprising:
obtaining data of voltage difference between maximum and minimum voltages of the battery cells within a battery pack of an electric vehicle;
determining an alert value based on the data of voltage difference, wherein the alert value is a combined value of the following factors: a slope of a mean battery cell voltage difference within a preset period of past time, a predicted mean battery cell voltage difference within a preset period of future time, and a minimum of battery cell voltage difference;
generating a predictive maintenance notice for the battery pack of the electric vehicle when the alert value is larger than a threshold value.

2. The method as claimed in claim 1, before obtaining the data of voltage difference between the maximum and minimum voltages of the battery cells within a battery pack of an electric vehicle, further comprises:
reporting, by on-board sensors and/or CAN bus of the electric vehicle, relevant data of individual battery cell voltages of the battery pack of the electric vehicle.

3. The method as claimed in claim 1, wherein determining an alert value based on the historical data of voltage difference, comprises:
analyzing, by a cloud-based server or an on-board computing device, a time series of relevant data of individual battery cell voltages of the battery pack to obtain the alert value.

4. The method as claimed in claim 1, wherein the alert value is a weighted average of the slope of the mean battery cell voltage difference, the predicted future mean battery cell voltage difference, and the minimum of battery cell voltage difference.

5. The method as claimed in claim 4, wherein the alert value L_{d} for a given time period is determined by the following formulas:
L_{d}=W₁*L₁+W₂*L₂+W₃*L₃, W₁+W₂+W₃=1;
wherein L₁, L₂ and L₃ respectively represent the slope of the mean battery cell voltage difference, the predicted future mean battery cell voltage difference, and the minimum of battery cell voltage difference; W₁, W₂ and W₃ are non-negative weight coefficients for L₁, L₂ and L₃, respectively.

6. The method as claimed in claim 5, wherein the weight coefficients W₁, W₂ and W₃ are determined according to a type of the battery pack.

7. The method as claimed in claim 1, the method further comprises:
obtaining a current alert value based on the alert values L_{d}, wherein the current alert value is a weighted average of the alert values over a preset number of time periods.

8. The method as claimed in claim 7, wherein the current alert Lₚ is determined by the following formula:
$${L}_{p} = \frac{{\sum }_{n = 1}^{N} ( {w}_{n} {L}_{d , n} )}{{\sum }_{n = 1}^{N} {w}_{n}}$$
wherein N represents a lookback window in time periods, and wₙ represents a weight coefficient of the n^{th} time period.

9. The method as claimed in claim 1, the method further comprises:
optimizing the threshold value based on reports of electric vehicles with battery pack error reported and electric vehicles with no battery pack error reported.

10. The method as claimed in claim 1, after the step of generating a predictive maintenance notice for the battery pack of the electric vehicle when the alert value is larger than a threshold value, further comprises:
sending the predictive maintenance notice to a designated terminal.

11. A system for monitoring a health condition of a battery pack, comprising:
an obtaining module, configured to obtain data of voltage difference between the maximum and minimum voltages of the battery cells within a battery pack of an electric vehicle;
a computing module, configured to calculate an alert value based on the data of voltage difference, wherein the alert value is a combined value of the following factors: a slope of a mean battery cell voltage difference within a preset period of past time, a predicted mean battery cell voltage difference within a preset period of future time, and a minimum of battery cell voltage difference;
a generating module, configured to generate a predictive maintenance notice for the battery pack of the electric vehicle when the alert value is larger than a threshold value.

12. The system as claimed in claim 11, wherein the alert value is a weighted average of the slope of the mean battery cell voltage difference, the predicted mean battery cell voltage difference, and the minimum of battery cell voltage difference.

13. The system as claimed in claim 12, wherein the alert value L_{d} for a given time period is determined by the following formulas:
L_{d}=W₁*L₁+W₂*L₂+W₃*L₃, W₁+W₂+W₃=1;
wherein L₁, L₂ and L₃ respectively represent the slope of the mean battery cell voltage difference, the predicted future mean battery cell voltage difference, and the minimum of battery cell voltage difference; W₁, W₂ and W₃ are non-negative weight coefficients for L₁, L₂ and L₃, respectively.

14. The system as claimed in claim 13, wherein the weight coefficients W₁, W₂ and W₃ are determined according to a type of the battery pack.

15. The system as claimed in claim 11, the obtaining module is further configured to:
obtain a current alert value based on the alert values L_{d}, wherein the current alert value is a weighted average of the alert values over a preset number of time periods.

16. The system as claimed in claim 15, wherein the current alert Lₚ is determined by the following formula:
$${L}_{p} = \frac{{\sum }_{n = 1}^{N} ( {w}_{n} {L}_{d , n} )}{{\sum }_{n = 1}^{N} {w}_{n}}$$
wherein N represents a lookback window in time periods, and wₙ represents a weight coefficient of the n^{th} time period.

17. The system as claimed in claim 11, the system further comprises:
an optimizing module, configured to optimize the threshold value based on reports of electric vehicles with battery pack error reported and electric vehicles with no battery pack error reported.

18. The system as claimed in claim 11, the system further comprises:
a sending module, configured to send the predictive maintenance notice to a designated terminal.

19. A non-volatile computer readable storage medium, in which a program is stored, the program is configured to be executed by a computer to perform the method as claimed in claim 1.

20. An electric vehicle, which comprises a system as claimed in claim 11.
